(19) United States
(12) Patent Application Publication
(10) Pub. No.: US 2026/0227702 A1
(43) Pub. Date: Aug. 6, 2026

(54) PATTERN FORMING METHOD AND METHOD FOR PRODUCING SEMICONDUCTOR DEVICE

(71) Applicant: Kioxia Corporation, Tokyo (JP)

(72) Inventors: Genna HASEGAWA, Yokkaichi (JP); Hisako AOYAMA, Yokkaichi (JP)

(21) Appl. No.: 19/310,376

(22) Filed: Aug. 26, 2025

(30) Foreign Application Priority Data
Feb. 5, 2025 (JP) 2025-017260

(51) Int. Cl. G03F 7/38; G03F 7/16; G03F 7/20; H01L 21/027; H01L 21/033; H01L 21/311; H10B 43/27; H10B 43/30; H10D 30/01; H10D 30/69

(52) U.S. Cl. CPC G03F 7/38; G03F 7/162; G03F 7/167; G03F 7/2004; H10D 30/0413; H10P 50/73; H10B 43/27; H10B 43/30; H10D 30/693; H10P 76/20; H10P 76/405; H10P 76/4085

(57) ABSTRACT

In a pattern forming method, a first film having a first pattern is formed on a workpiece, and a second film is formed on the first film. Next, the second film is etched back, the first film is removed, and a second pattern obtained by inverting the first pattern is formed in the second film. Next, a crosslinking rate of the second film is increased, and the workpiece is etched using the second pattern as a mask.

### CROSS-REFERENCE TO RELATED APPLICATION(S)

This application is based upon and claims the benefit of priority from Japanese Patent Application No. 2025-017260, filed Feb. 5, 2025, the entire contents of which are incorporated herein by reference.

### FIELD

Embodiments described herein relate generally to a pattern forming method and a method for producing a semiconductor device.

### BACKGROUND

To form a pattern on a workpiece, a reverse film may be formed on a resist pattern in a lithography step. In general, the heat resistance of the resist is low, and the formation of the reverse film supplied onto the resist is performed at a relatively low temperature.

Examples of related art include JP-A-2019-145714 and WO2017/150261.

### DESCRIPTION OF THE DRAWINGS

FIG. 1 is a cross-sectional view illustrating an example of a pattern forming method according to a first embodiment.

FIG. 2 is a cross-sectional view illustrating an example of the pattern forming method according to the first embodiment.

FIG. 3 is a cross-sectional view illustrating an example of the pattern forming method according to the first embodiment.

FIG. 4 is a cross-sectional view illustrating an example of the pattern forming method according to the first embodiment.

FIG. 5 is a cross-sectional view illustrating an example of the pattern forming method according to the first embodiment.

FIG. 6 is a cross-sectional view illustrating an example of the pattern forming method according to the first embodiment.

FIG. 7 is a cross-sectional view illustrating an example of the pattern forming method according to the first embodiment.

FIG. 8 is a flowchart illustrating an example of a procedure of the pattern forming method according to the first embodiment.

FIG. 9 is a cross-sectional view illustrating an example of a pattern forming method according to a second embodiment.

FIG. 10 is a cross-sectional view illustrating an example of the pattern forming method according to the second embodiment.

FIG. 11 is a cross-sectional view illustrating an example of the pattern forming method according to the second embodiment.

FIG. 12 is a cross-sectional view illustrating an example of the pattern forming method according to the second embodiment.

FIG. 13 is a cross-sectional view illustrating an example of the pattern forming method according to the second embodiment.

FIG. 14 is a cross-sectional view illustrating an example of the pattern forming method according to the second embodiment.

FIG. 15 is a cross-sectional view illustrating an example of the pattern forming method according to the second embodiment.

FIG. 16 is a cross-sectional view illustrating an example of the pattern forming method according to the second embodiment.

FIG. 17 is a cross-sectional view illustrating an example of a method for producing a semiconductor device according to a third embodiment.

FIG. 18 is a cross-sectional view illustrating an example of the method for producing a semiconductor device according to the third embodiment.

FIG. 19 is a cross-sectional view illustrating an example of the method for producing a semiconductor device according to the third embodiment.

FIG. 20 is a cross-sectional view illustrating an example of the method for producing a semiconductor device according to the third embodiment.

FIG. 21 is a cross-sectional view illustrating an example of the method for producing a semiconductor device according to the third embodiment.

FIG. 22 is a cross-sectional view illustrating an example of the method for producing a semiconductor device according to the third embodiment.

### DETAILED DESCRIPTION

Embodiments provide a pattern forming method having high formation accuracy and a method for producing a semiconductor device by using a mask having high etching resistance.

In general, according to one embodiment, in a pattern forming method according to the present embodiment, a first film having a first pattern is formed on a workpiece, and a second film is formed on the first film. Next, the second film is etched back, the first film is removed, and a second pattern obtained by inverting the first pattern is formed in the second film. Next, a crosslinking rate of the second film is improved, and the workpiece is etched using the second pattern as a mask.

Embodiments will be described with reference to the drawings. The embodiments do not limit the present disclosure. The drawings are schematic or conceptual. The proportions of various parts are not necessarily the same as those in reality. In the description and the drawings, elements similar to those previously described with reference to a preceding drawing are denoted by the same reference numerals, and a detailed description thereof will be appropriately omitted.

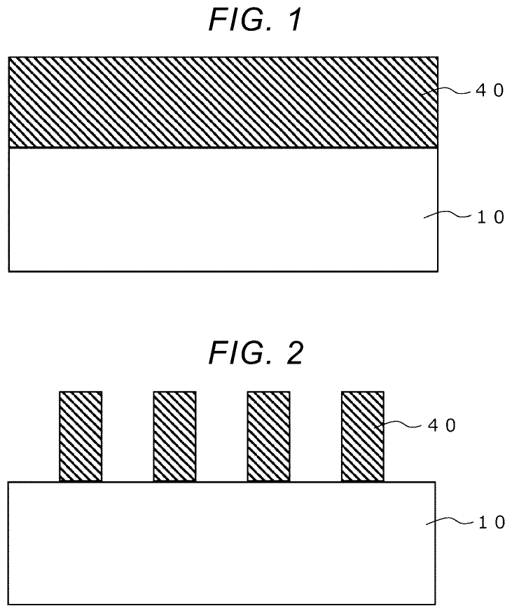

(First Embodiment) FIGS. 1 to 7 are cross-sectional views illustrating an example of a pattern forming method for a workpiece 10 according to a first embodiment.

The workpiece 10 is, for example, a silicon substrate. A device formed on the workpiece 10 is, for example, a semiconductor device such as an NAND electrically erasable programmable read-only memory (EEPROM).

First, as illustrated in FIG. 1, a resist film 40 is formed on the workpiece 10. The resist film 40 is an organic film containing C, H, and O. For example, a novolac resin, a methacrylate resin, or an acrylate resin is used as the resist film 40. The resist film 40 is an example of a first film.

Next, as illustrated in FIG. 2, the resist film 40 is patterned using a lithography technique. At this time, the resist film 40 is patterned with a pattern that is the inverse of the pattern to be transferred to the workpiece 10. The pattern formed in the resist film 40 is an example of a first pattern. The lithography technique may be any of a photolithography technique, a nano-imprint lithography (NIL) technique, or a directed self-assembly (DSA) technique. In the present embodiment, a case of performing patterning by the NIL technique will be described.

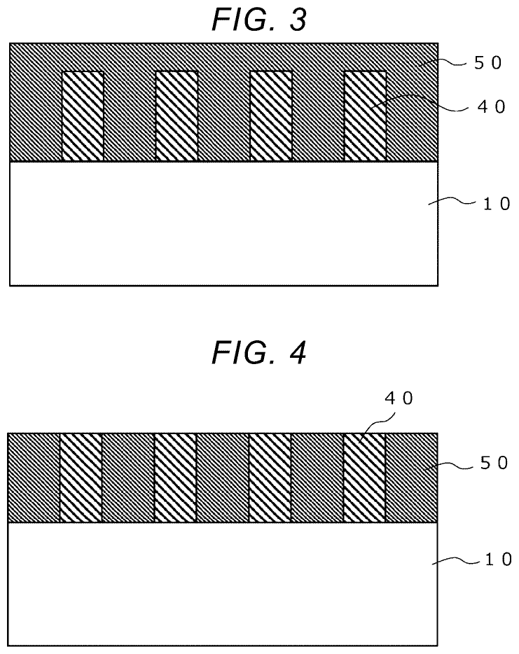

Next, as illustrated in FIG. 3, a reverse film 50 is formed on the patterned resist film 40. The reverse film 50 is formed by, for example, a spin coating method and is also filled between the patterns of the resist film 40. The reverse film 50 is applied onto the resist film 40 and then cured by being heated at a first temperature. The first temperature is a temperature at which a shape of the resist film 40 does not deteriorate (details will be described later). The temperature at which the shape of the resist film 40 does not deteriorate is, for example, a temperature at which a dimension of the resist film 40 after heating falls within an error of ±10% with respect to a desired dimension.

The reverse film 50 is an organic film containing silicon (Si), and for example, an Si-containing film that can be applied by a spin coating method is used. For example, spin-on-glass (SOG) is used as the reverse film 50. Alternatively, the reverse film 50 may be an organic film containing a metal. Hereinafter, in the present embodiment, a case in which the SOG is used as the reverse film 50 will be described. The reverse film 50 is an example of a second film.

Hereinafter, “crosslinking” and “crosslinking rate” will be described.

As one of the methods for improving processing resistance, there is a method of promoting “crosslinking” by applying heat to the material. “Crosslinking” is a “chemical reaction in which molecules in the material are bonded together”.

When a “proportion of molecules bonded together in the material through crosslinking” is set as a “crosslinking rate”, the crosslinking rate of the material can be increased by heating the material. For example, as crosslinking progresses in the reverse film 50, the crosslinking rate increases, and the resistance to processing, such as reactive ion etching (RIE), to be described later, increases.

Hereinafter, the first temperature and a first crosslinking rate will be described. In FIG. 3, when the reverse film 50 is heated at a temperature significantly higher than a glass transition temperature (Tg) of the resist film 40 in a state in which the resist film 40 is present, the shape of the resist film 40 may deteriorate. Therefore, in FIG. 3, the reverse film 50 is heated at “a temperature at which the shape of the resist film 40 does not deteriorate”, and this temperature is set as the first temperature. The first temperature is, for example, equal to or lower than the Tg+50° C. of the resist film 40 at which the reverse film 50 can be formed. Specifically, the first temperature is, for example, about 150 degrees or lower. By heating the reverse film 50 at such a first temperature to implement film formation, the reverse film 50 can maintain a remaining pattern even after removal of the resist film 40 to be described later. A crosslinking rate after heating the reverse film 50 at the first temperature is set as the first crosslinking rate.

Next, as illustrated in FIG. 4, the reverse film 50 is removed until the resist film 40 is exposed. The reverse film 50 may be removed by being etched back by dry etching. In the case of performing etch back, as a gas species for dry etching, a CF-based gas or a mixed gas containing a CF-based gas may be selected, or the reverse film 50 may be etched back using ion beam etching using Ar ions.

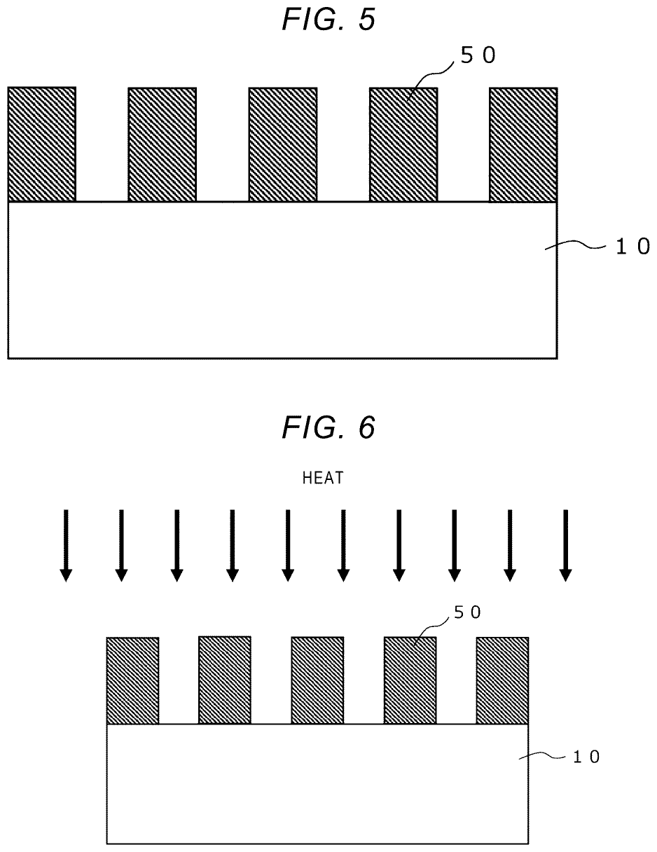

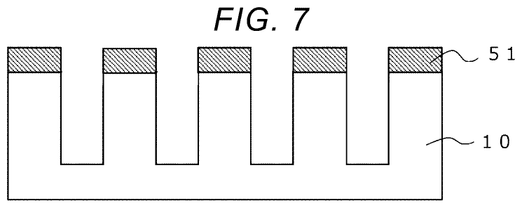

Next, as illustrated in FIG. 5, the resist film 40 is selectively removed while leaving the reverse film 50. The resist film 40 is removed using, for example, the RIE method. Since the resist film 40 is provided on a removal pattern of the workpiece 10, the reverse film 50 is left on the remaining pattern of the workpiece 10. A pattern formed in the reverse film 50 is an example of a second pattern. The removal pattern of the workpiece 10 is a pattern in a portion to be removed of the workpiece 10 in an etching step. The remaining pattern of the workpiece 10 is a reverse pattern of the removal pattern and is a pattern in a portion remaining without being of the workpiece 10 etched in the etching step (see FIG. 7).

Next, as illustrated in FIG. 6, heating is performed to improve a crosslinking rate of the remaining reverse film 50. The reverse film 50 is heated at a second temperature higher than the temperature at the time of heating in FIG. 3. The second temperature is higher than the first temperature and is a temperature at which crosslinking of the reverse film 50 is promoted (details will be described later). By performing the heat processing at a high temperature (for example, the second temperature), the processing resistance of the reverse film 50 is improved compared to before the processing of promoting the crosslinking of the reverse film 50.

The second temperature and a second crosslinking rate will be described below. In FIG. 6, an etching selectivity between the workpiece 10 and the reverse film 50 is improved by heating the reverse film 50 at a “temperature higher than the first temperature and at which the crosslinking of the reverse film 50 is promoted”. The second temperature is, for example, about 180 degrees to 250 degrees. By processing the reverse film 50, namely, by heating the reverse film 50 at the second temperature, the crosslinking is promoted, and the reverse film 50 has the second crosslinking rate. The second crosslinking rate is larger than the first crosslinking rate. The reverse film 50 having the second crosslinking rate is set as a reverse film 51.

Although a specific example of the second temperature is described, the second temperature may be lower than 180 degrees or higher than 250 degrees as long as the reverse film 50 can be heated to have a desired crosslinking rate and is not damaged, such as cracked or shrunk.

As the processing of improving the crosslinking rate of the reverse film 50 having a remaining pattern after the resist film 40 is selectively removed, ultraviolet energy (in the form of rays) may be emitted. That is, when the ultraviolet emission is used to improve the crosslinking rate of the reverse film 50, the ultraviolet can be emitted until the reverse film 50 reaches a desired etching selectivity.

When the crosslinking rate of the reverse film 50 is increased by ultraviolet emission, it is possible to reduce thermal damage to the workpiece 10 and a film or a pattern formed under the workpiece 10, that is, a change in film quality or deterioration in pattern shape.

Next, as illustrated in FIG. 7, the workpiece 10 is etched using the reverse film 51 as a mask. The workpiece 10 is etched by, for example, the RIE method.

In FIG. 7, when the workpiece 10 is etched, the reverse film 51 having an improved processing resistance is used. Therefore, it is possible to prevent the progress of etching of the reverse film 51 in a vertical direction, which is an etching processing direction, and a horizontal direction, which is a direction perpendicular to the etching processing direction in the reverse film 51. Accordingly, it is possible to reduce shape variation and dimensional variation of the workpiece 10 after processing.

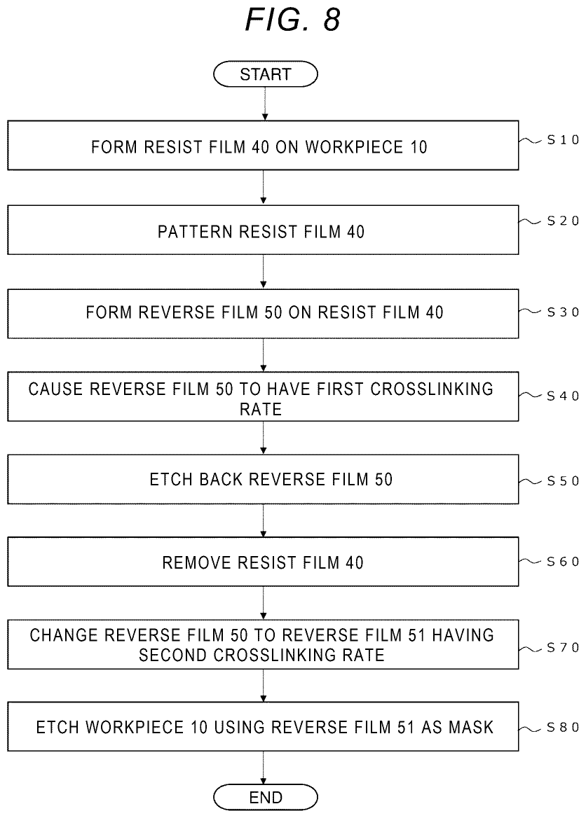

FIG. 8 is a flowchart illustrating an example of a procedure of the pattern forming method according to the first embodiment.

First, the resist film 40 is formed on the workpiece 10 (S10).

Next, the resist film 40 is patterned using the lithography technique (S20). At this time, the reverse pattern of a pattern to be transferred to the workpiece 10 is formed in the resist film 40.

Next, the reverse film 50 is supplied onto the patterned resist film 40 (S30). At this time, the reverse film 50 may be applied by the spin coating method.

The reverse film 50 is applied onto the resist film 40 and then heated at a first temperature to have the first crosslinking rate (S40).

Next, the reverse film 50 is etched back by dry etching processing until the resist film 40 is exposed (S50).

Next, the reverse film 50 is etched back until the resist film 40 is exposed, and then the resist film 40 is selectively removed while leaving the reverse film 50 (S60). The resist film 40 is removed using, for example, the RIE method.

Next, the remaining reverse film 50 is heated at the second temperature to form the reverse film 51 having the second crosslinking rate (S70). In other words, the reverse film 50 is heated at the second temperature after the removal of the resist film 40, and the crosslinking further proceeds. That is, the second temperature during heating in S70 is higher than the first temperature during heating in S40, and the second crosslinking rate is larger than the first crosslinking rate. The second temperature is a temperature at which the crosslinking of the reverse film 50 is promoted. The heated reverse film 50 is improved in processing resistance as a result of the progress of crosslinking, as compared with the case of being heated at the first temperature (S40).

In S70, the reverse film 50 having the remaining pattern after the selective removal of the resist film 40 may be irradiated with ultraviolet rays to increase the crosslinking rate of the reverse film 50, thereby forming the reverse film 51.

Finally, the workpiece 10 is etched using the reverse film 51 as a mask (S80). The workpiece 10 is etched by, for example, the RIE method.

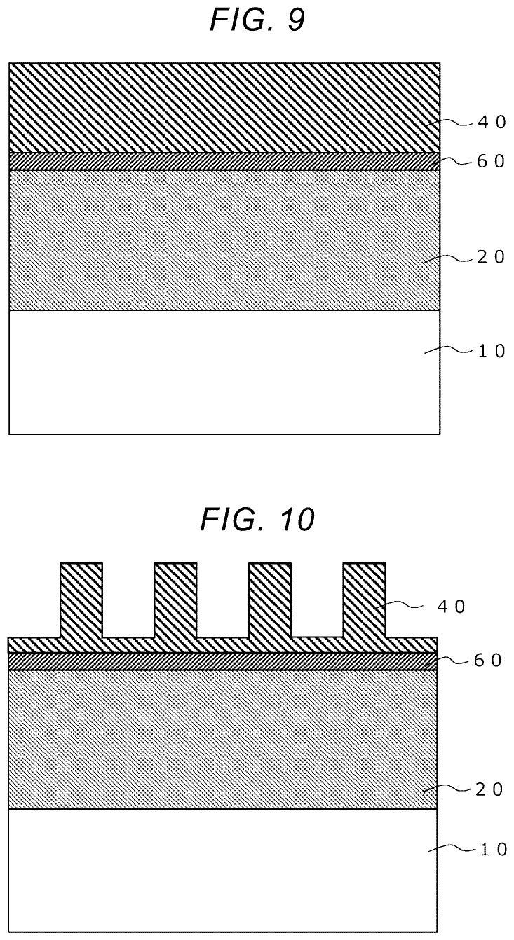

(Second Embodiment) FIGS. 9 to 16 are cross-sectional views illustrating an example of a pattern forming method for the workpiece 10 according to a second embodiment. FIGS. 9 to 16 have a content in common with the procedures in FIGS. 1 to 7 according to the first embodiment, and the following will focus on the differences and provide a brief description.

The workpiece 10 may be the same as that in the first embodiment.

As illustrated in FIG. 9, a sacrificial film 20, an adhesive film 60, and the resist film 40 are formed on the workpiece 10, with the sacrificial film 20 between the resist film 40 and the workpiece 10. In the present embodiment, a case in which a spin-on-carbon (SOC) film is used as the sacrificial film 20 and an organic film containing C, H, and O is used as the resist film 40 will be described. The sacrificial film 20 is an example of a third film.

In the present embodiment, a case of performing patterning by the NIL technique will be described. The sacrificial film 20 and the resist film 40 adhere to each other via the adhesive film 60. The adhesive film 60 contains, for example, molecules that bond the sacrificial film 20 and the resist film 40 together through hydrogen bonds or covalent bonds.

Next, as illustrated in FIG. 10, the resist film 40 is patterned using the NIL technique. The resist film 40 may remain thinly on the adhesive film 60 in recesses of the resist film 40, or the resist film 40 may be completely removed.

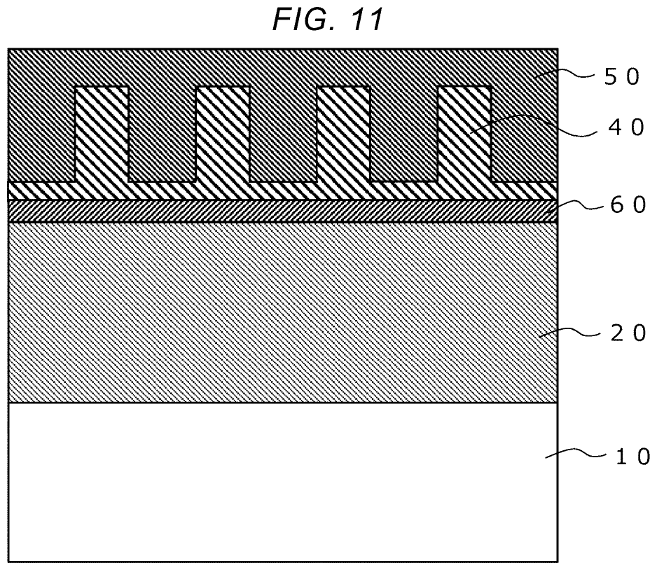

Next, as illustrated in FIG. 11, the reverse film 50 is formed on the patterned resist film 40. The reverse film 50 is an organic film containing silicon (Si) and may be the same as in the first embodiment. The reverse film 50 is applied onto the resist film 40 and then heated at a first temperature. The first temperature is a temperature at which a shape of the resist film 40 does not deteriorate, as in the first embodiment.

By heating the reverse film 50 at the first temperature to implement film formation, the reverse film 50 can maintain a remaining pattern even after removal of the resist film 40 to be described later. The reverse film 50 is heated at the first temperature to have a first crosslinking rate.

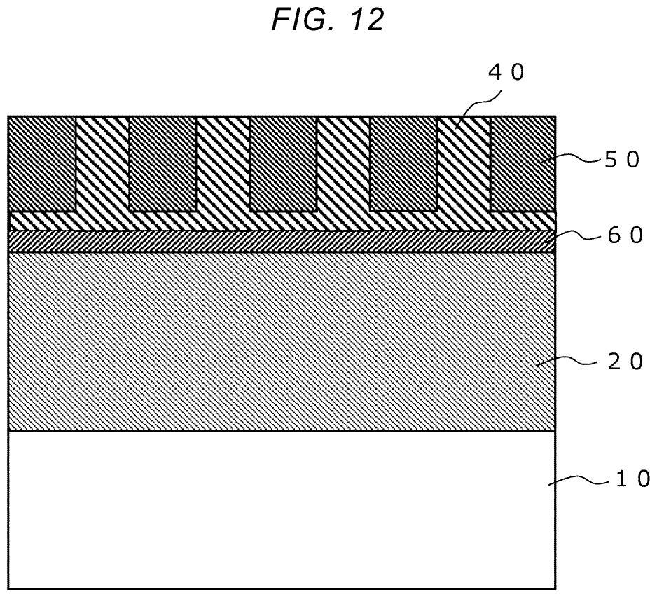

Next, as illustrated in FIG. 12, the reverse film 50 is removed until the resist film 40 is exposed.

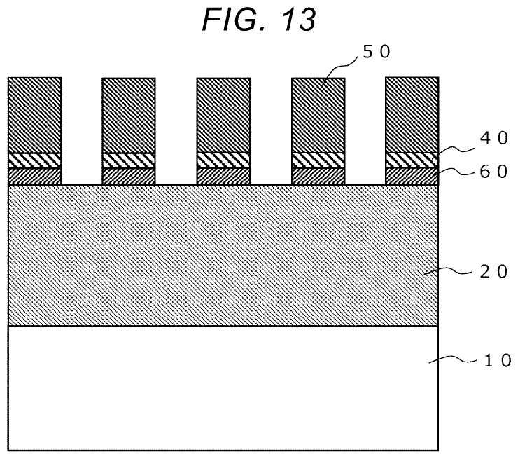

Next, as illustrated in FIG. 13, the resist film 40 is selectively removed while leaving the reverse film 50. The reverse film 50 is left on the remaining pattern of the workpiece 10. At this time, the adhesive film 60 formed under the removed resist film 40 may also be removed. It is noted that the resist film 40 and the adhesive film 60 formed under the reverse film 50 remain.

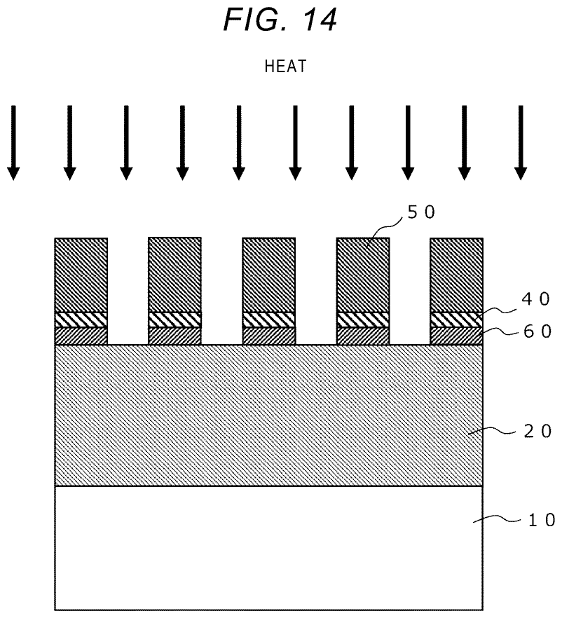

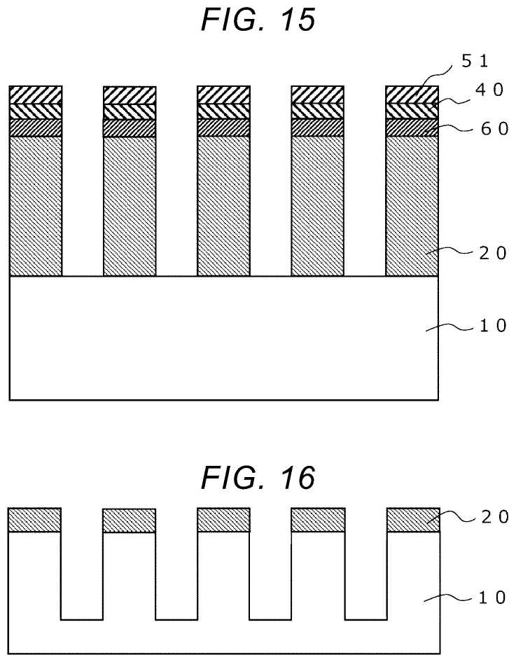

Next, as illustrated in FIG. 14, heating is performed to improve a crosslinking rate of the remaining reverse film 50. The reverse film 50 is heated at a second temperature higher than the temperature at the time of heating in FIG. 11. The second temperature is a temperature higher than the first temperature and at which crosslinking of the reverse film 50 is promoted, and may be the same as in the first embodiment. By heating the reverse film 50 at the second temperature, the crosslinking is promoted, and the reverse film 50 has a second crosslinking rate. The second crosslinking rate is the same as in the first embodiment. The reverse film 50 having the second crosslinking rate is set as the reverse film 51.

By performing the heat processing at a high temperature (for example, the second temperature), the processing resistance of the reverse film 50 is improved compared to before the processing of promoting the crosslinking of the reverse film 50 is performed. That is, by heating the reverse film 50 at the second temperature, the crosslinking rate of the reverse film 50 is improved, and the etching selectivity between the sacrificial film 20 and the reverse film 50 is also improved. Therefore, the processing resistance of the reverse film 50 after heating at the second temperature is larger than the processing resistance of the sacrificial film 20. Therefore, after the sacrificial film 20 is etched, the reverse film 51 can be left on the sacrificial film 20 by a predetermined thickness. The second temperature is, for example, about 180 degrees to 250 degrees.

As the processing of improving the crosslinking rate of the reverse film 50 after the resist film 40 is selectively removed, ultraviolet rays may be emitted. When the ultraviolet emission is used to improve the crosslinking rate of the reverse film 50, the ultraviolet can be emitted until the reverse film 50 reaches a desired etching selectivity.

When the crosslinking rate of the reverse film 50 is increased by ultraviolet emission, it is possible to reduce thermal damage to the sacrificial film 20 and a film or a pattern formed under the sacrificial film 20, that is, a change in film quality or deterioration in pattern.

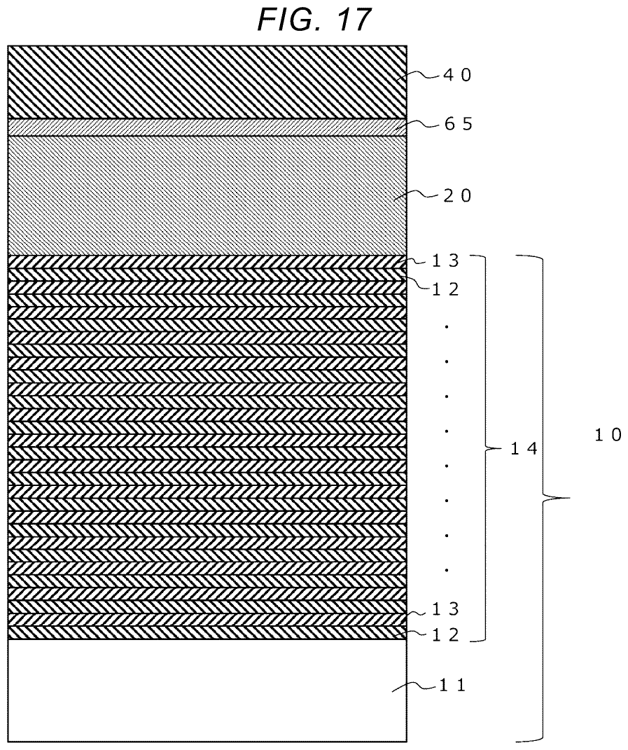

After the reverse film 50 is heated, as illustrated in FIG. 15, the sacrificial film 20 is etched using the reverse film 51 as a mask until the workpiece 10 is exposed. The sacrificial film 20 is etched by, for example, the RIE. When the workpiece 10 is exposed, the reverse film 51 remains by a predetermined thickness.

Next, as illustrated in FIG. 16, the workpiece 10 is etched using the reverse film 51, the resist film 40, the adhesive film 60, and the sacrificial film 20 as a mask. The workpiece 10 is etched by, for example, the RIE method.

In FIG. 15, when the sacrificial film 20 is etched, the reverse film 50 is heated at the second temperature to increase the crosslinking rate to form the reverse film 51 with improved etching resistance. Therefore, the same effects as those of the first embodiment can be obtained.

(Third Embodiment) FIGS. 17 to 22 are cross-sectional views illustrating an example of a method for producing a semiconductor device according to a third embodiment.

The workpiece 10 according to the present embodiment is a semiconductor device, and is, for example, a memory. Specifically, the workpiece 10 may be a semiconductor device such as a NAND EEPROM. The NAND EEPROM includes, for example, a three-dimensional memory cell array having a three-dimensional structure, and a peripheral circuit that is provided on the same substrate as the memory cell array and controls the memory cell array. The peripheral circuit is provided on a semiconductor substrate. The memory cell array is provided above the peripheral circuit.

The method for producing a semiconductor device according to the present embodiment will be described with reference to a case in which the method is used to form a memory hole of a NAND EEPROM. However, the present embodiment is not limited thereto, and the method for producing a semiconductor device according to the present embodiment may be used for other semiconductor devices.

FIGS. 17 to 20 illustrate a step in which the peripheral circuit is already formed on the semiconductor substrate and the memory cell array is formed above the peripheral circuit. FIGS. 17 to 20 have a content in common with the procedures in FIGS. 1 to 7 according to the first embodiment, and the following will focus on the differences and provide a brief description.

After the peripheral circuit is formed on the semiconductor substrate, an interlayer insulating film 11 is formed on the peripheral circuit. A structure such as a source line may be provided between the interlayer insulating film 11 and a stacked body 14 to be described later.

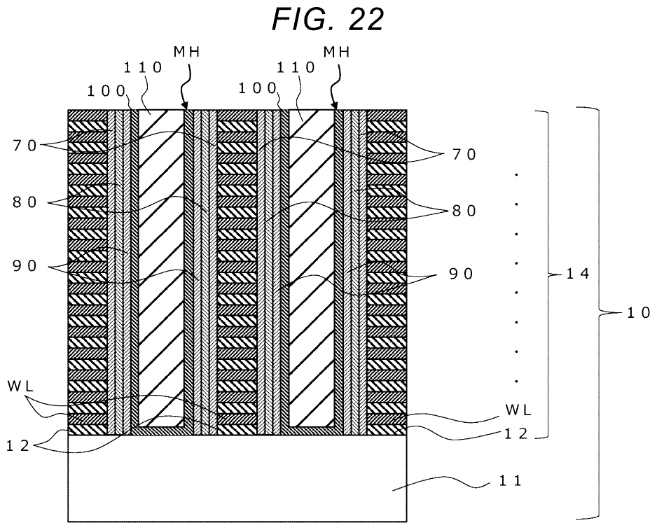

First, as illustrated in FIG. 17, the stacked body 14 including alternating layers of a plurality of silicon oxide films 12 and a plurality of silicon nitride films 13 is formed on the interlayer insulating film 11. The silicon nitride film 13 is replaced with a conductive material such as tungsten in a later step. This conductive material functions as a word line (WL in FIG. 22). The silicon oxide film 12 insulates the word lines WL adjacent to each other in a stacking direction (a direction perpendicular to a surface of the semiconductor substrate) of the stacked body 14.

The stacked body 14 is processed later as the workpiece 10. For example, a pattern having a high aspect ratio, such as a memory hole, will be formed later in the stacked body 14.

Thereafter, the sacrificial film 20 is formed on the workpiece 10. For example, a CVD-C film is used as the sacrificial film 20. Hereinafter, a case in which a CVD-C film is used as the sacrificial film 20 will be described.

After the sacrificial film 20 is formed on the workpiece 10, an antireflection film 65 is formed on the sacrificial film 20. The antireflection film 65 is, for example, an organic material such as a methacrylic resin containing a substituent having an absorption band in an exposure wavelength region. Next, the resist film 40 is applied onto the antireflection film 65. In an exposure step of the resist film 40, the antireflection film 65 prevents reflection from the sacrificial film 20 and prevents excessive exposure of the resist film 40 caused by reflected light.

Next, the resist film 40 is patterned using the lithography technique. The patterning of the resist film 40 may be the same as in FIG. 2 or 10. In the present embodiment, a case in which patterning is performed by a photolithography technique will be described.

As in the first embodiment, the resist film 40 is patterned to have a pattern that is the inverse of the pattern to be transferred to the workpiece 10.

Next, the reverse film 50 is formed on the patterned resist film 40. The formation of the reverse film 50 may be the same as in FIGS. 3 and 11. The reverse film 50 is applied onto the resist film 40 and then heated at the first temperature.

The reverse film 50 may be the same as in the first embodiment, and an Si-containing film that can be applied by, for example, a spin coating method is used.

The reverse film 50 is heated at the first temperature. The first temperature is a temperature at which a shape of the resist film 40 does not deteriorate, as in the first embodiment. By heating the reverse film 50 at the first temperature to implement film formation, the reverse film 50 can be maintained even after removal of the resist film 40 to be described later. The reverse film 50 is heated at the first temperature to have a first crosslinking rate.

Next, after the reverse film 50 is removed by etch-back or the like until the resist film 40 is exposed, the resist film 40 is selectively removed while leaving the reverse film 50. At this time, the antireflection film 65 formed under the resist film 40 may also be selectively removed.

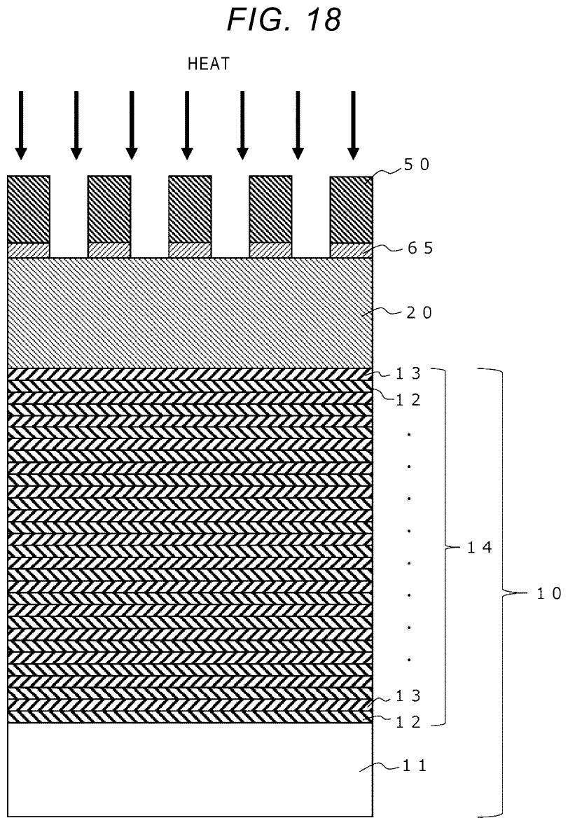

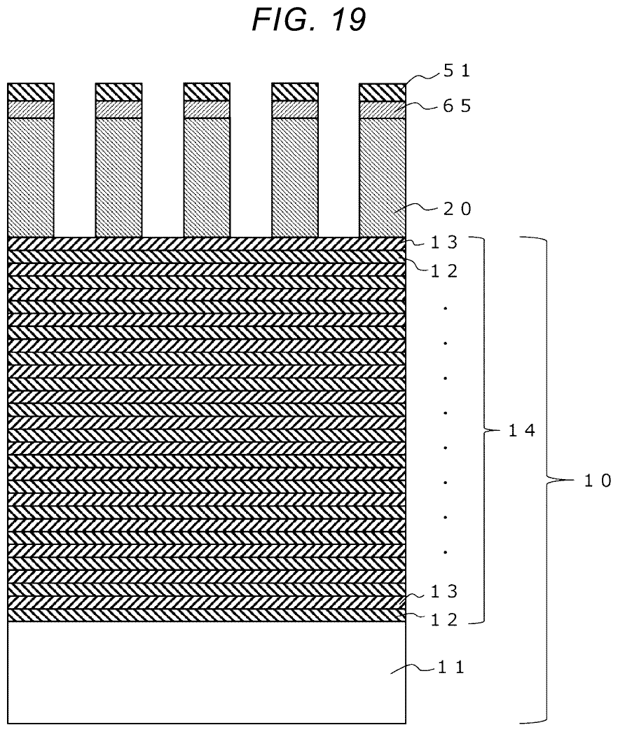

Next, as illustrated in FIG. 18, heating is performed to improve a crosslinking rate of the remaining reverse film 50. The reverse film 50 is heated at a second temperature. The second temperature may be the same as in the first embodiment. By heating the reverse film 50 at the second temperature, the crosslinking is promoted, and the reverse film 50 has a second crosslinking rate. The second crosslinking rate may be the same as in the first embodiment, and the reverse film 50 having the second crosslinking rate is set as the reverse film 51.

By performing the heat processing at a high temperature (for example, the second temperature), the etching selectivity between the sacrificial film 20 and the reverse film 50 is improved as in the second embodiment. Therefore, after the sacrificial film 20 is etched, it is possible to have processing resistance such that the reverse film 51 can be left on the sacrificial film 20 by a predetermined thickness.

As the processing of improving the crosslinking rate of the reverse film 50 after the resist film 40 is selectively removed, ultraviolet rays may be emitted as in the first embodiment.

After the reverse film 50 is heated, as illustrated in FIG. 19, the sacrificial film 20 is etched using the reverse film 51 and the antireflection film 65 as a mask until the workpiece 10 is exposed. The sacrificial film 20 is etched by, for example, the RIE. When the workpiece 10 is exposed, the reverse film 51 preferably remains by a predetermined thickness.

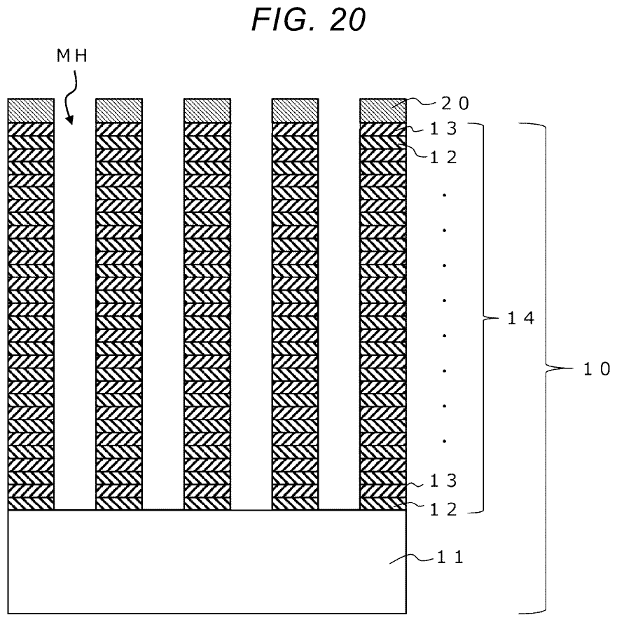

Next, as illustrated in FIG. 20, the workpiece 10 is etched using the reverse film 51, the antireflection film 65, and the sacrificial film 20 as a mask. The workpiece 10 is etched by, for example, the RIE. Memory holes MH are formed in the stacked body 14 by etching the workpiece 10.

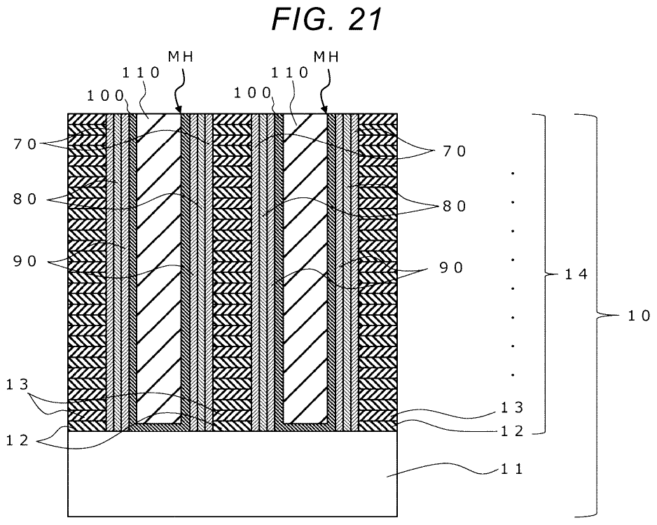

FIGS. 21 and 22 are cross-sectional views illustrating an example of the method for producing a semiconductor device according to the third embodiment.

Next, as illustrated in FIG. 21, in the memory hole MH, a block film 70, a charge trap film 80, a tunnel film 90, a channel layer 100, and a core 110 are formed in this order from the stacked body 14 toward a center of the memory hole MH.

The block film 70 is provided between the charge trap film 80 and the word line WL illustrated in FIG. 22 and prevents charges trapped by the charge trap film 80 from leaking to the word line. For example, a silicon oxide film is used as the block film 70.

The charge trap film 80 takes in charges (for example, electrons) from the channel layer 100 via the tunnel film 90 and captures the charges at the time of writing data. The data can be written in each memory cell by capturing the charges in a portion of the charge trap film 80 corresponding to the word line WL. The charge trap film 80 releases the charges to the channel layer 100 via the tunnel film 90 at the time of data erasing. The data in each memory cell can be erased by discharging the charges of a portion of the charge trap film 80 corresponding to the word line WL. For example, a silicon nitride film is used as the charge trap film 80.

The tunnel film 90 prevents the charges captured by the charge trap film 80 from leaking to the channel layer 100 while allowing the charges to pass between the channel layer 100 and the charge trap film 80 during data writing and data erasing. For example, a silicon oxide film is used as the tunnel film 90.

The channel layer 100 is formed along a side surface and a bottom surface of the core 110. Accordingly, the channel layer 100 is connected to the source line formed under the stacked body 14. For example, polysilicon is used as the channel layer 100.

The core 110 has, for example, a rectangular or cylindrical pillar shape. The channel layer 100, the tunnel film 90, the charge trap film 80, and the block film 70 are provided on the side surface of the core 110 and together form a pillar structure. For example, a silicon oxide film is used as the core 110.

Thereafter, a slit (not illustrated) is formed in the stacked body 14, and the silicon nitride film 13 is removed via the slit.

Finally, as illustrated in FIG. 22, instead of the silicon nitride film 13, a metal such as tungsten is formed between the silicon oxide films 12 adjacent in the stacking direction of the stacked body 14. Accordingly, the word line WL is formed. Thereafter, a contact plug or a bit line (not illustrated) electrically connected to the core 110 is formed, thereby completing the NAND EEPROM.

An intersection of the word line WL and the pillar structure functions as a memory cell. The data can be written in the memory cell corresponding to the word line WL by capturing the charges in the portion of the charge trap film 80 corresponding to each word line WL.

Also in the method for producing a semiconductor device according to the third embodiment, when the sacrificial film 20 is etched in FIG. 19, the reverse film 50 is heated at the second temperature to increase the crosslinking rate, and the reverse film 51 with improved processing resistance is formed. Therefore, the same effects as those of the first embodiment can be obtained. Therefore, shape variation and dimensional variation of the workpiece 10 after processing are reduced, and the pattern formation accuracy is improved. Therefore, also in the third embodiment, the stacked body 14 included in the workpiece 10 can be processed into a fine pattern having a high aspect ratio.

While certain embodiments have been described, these embodiments have been presented by way of example only, and are not intended to limit the scope of the disclosure. Indeed, the novel embodiments described herein may be embodied in a variety of other forms; furthermore, various omissions, substitutions, and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A pattern forming method comprising:
forming a first film having a first pattern on a workpiece;
forming a second film on the first film;
etching the second film, removing the first film, and forming a second pattern obtained by inverting the first pattern on the second film;
processing the second film to increase a crosslinking rate of the second film; and
etching the workpiece using the second pattern as a mask.

2. The pattern forming method according to claim 1, wherein the processing comprises:
heating the second film.

3. The pattern forming method according to claim 2, wherein
the second film is heated at a first temperature when forming the second film on the first film, and
the pattern forming method further includes heating the second film at a second temperature higher than the first temperature to increase the crosslinking rate of the second film.

4. The pattern forming method according to claim 2, wherein
when the second film is formed on the first film, the second film has a first crosslinking rate, and
when the second film is processed, the crosslinking rate of the second film is caused to increase to be a second crosslinking rate that is larger than the first crosslinking rate during the processing of the second film.

5. The pattern forming method according to claim 3, wherein
the first temperature is equal to or lower than a glass transition temperature (Tg)+50° C. of the first film.

6. The pattern forming method according to claim 3, wherein
the second temperature is a temperature at which the crosslinking rate of the second film is increased.

7. The pattern forming method according to claim 3, further comprising:
forming a third film on the workpiece before the first film is formed;
forming the first film on the workpiece such that the third film is disposed between the first film and the workpiece when forming the first film; and
etching the third film using the second pattern of the second film as a mask when etching the workpiece.

8. The pattern forming method according to claim 7, wherein
during etching of the workpiece, processing resistance of the second film is larger than processing resistance of the third film.

9. The pattern forming method according to claim 1, further comprising:
irradiating the second film with ultraviolet energy when crosslinking the second film.

10. The pattern forming method according to claim 1, wherein
the first film is an organic film containing C, H, and O.

11. The pattern forming method according to claim 1, wherein
the second film is an organic film containing Si or a metal.

12. The pattern forming method according to claim 11, wherein
the second film is spin-on-glass (SOG).

13. The pattern forming method according to claim 7, wherein
the third film is a chemical vapor deposition-carbon (CVD-C) film or a spin-on-carbon (SOC) film.

14. A method for producing a semiconductor device, the method comprising:
forming a first film having a first pattern on a workpiece formed on a semiconductor substrate of the semiconductor device;
forming a second film on the first film;
etching the second film, removing the first film, and forming a second pattern obtained by inverting the first pattern on the second film;
processing the second film to increase a crosslinking rate of the second film; and
etching the workpiece using the second pattern as a mask.

15. The method for producing a semiconductor device according to claim 14, wherein
the workpiece includes a stacked body in which a plurality of silicon oxide films and a plurality of silicon nitride films are alternately stacked.
